(19) United States
(12) Patent Application Publication
(10) Pub. No.: US 2005/0212572 A1
(43) Pub. Date: Sep. 29, 2005

(54) Power up clear (PUC) signal generators having input references that track process and temperature variations

(76) Inventors: Reed W. Adams, Plano, TX (US); Zbigniew J. Lata, Plano, TX (US)

Correspondence Address: TEXAS INSTRUMENTS INCORPORATED, P O BOX 655474, M/S 3999, DALLAS, TX, 75265, US

(21) Appl. No.: 10/811,587

(22) Filed: Mar. 29, 2004

(51) Int. Cl. H03L 7/00

(52) U.S. Cl. 327/143

(57) ABSTRACT

A power up clear (PUC) signal is generated, based on a value of a supply voltage VCC. A first circuit element (such as an n-channel MOSFET MN0) of a first conductivity type having a first characteristic threshold voltage, and a second circuit element (such as p-channel MOSFET MP0) of a second conductivity type having a second characteristic threshold voltage, are provided in a PUC signal generating circuit. A first circuit portion (including MN0, R0) is configured to provide a first comparison input signal VIN−, and a second circuit portion (including MP0, R1, R2, and, switchably, R3) is configured to provide a second comparison input signal VIN+. A comparator COMP compares the first and second comparison input signals VIN−, VIN+, to cause the PUC signal to transition to an active state when one of the first and second comparison signals crosses another of the first and second comparison signals, in response to an increasing magnitude of the supply voltage during power up. The PUC signal generator automatically tracks (compensates for) device process variations and temperature changes, without reference to any externally supplied reference voltages or currents or bias voltages or currents.

### BACKGROUND OF THE INVENTION

1. Field of the Invention

The invention generally relates to power up clear (PUC) signal generator arrangements. More particularly, the invention relates to PUC signal generating arrangements that automatically compensate for variations in device processes and changes in temperature.

2. Related Art

A digital circuit generally requires an enable signal to begin its operation when its supply voltage becomes high enough. Such an enable signal is generated by what may be termed a power up clear (PUC) circuit that monitors the circuit's main supply voltage (or voltage derived from the main supply). When the voltage supply exceeds a sufficient voltage level (sometimes called a “trip point”), the PUC signal is generated to enable the circuits to perform their tasks; otherwise they remain disabled.

Conventionally, it has been difficult to reliably and adaptively determine a proper level of the trip point of PUC circuits with respect to voltage “headroom” experienced in the technology of the circuits. Here, headroom refers to the amount of voltage on the supply that is above and beyond the absolute minimum voltage required for the circuit to operate properly. For example, if the circuit needs a minimum of 1.3 volts to operate, and the supply is presently at 2.0v, the headroom would be equal to 0.7 volts.

It would be desirable that the trip point be defined in such a manner as to automatically compensate for process variations, temperature, power supply voltage minimum and maximum values, supply voltage dips in case of load transient, and so forth. If the trip point is set too low, the PUC circuit may generate a PUC signal, but circuits will not operate properly due to their low power supply voltage, and the device may start up in a random state instead of a desired default state. Conversely, if the trip point is set too high, load transient or power supply voltage variation can cause an unwanted resetting of the device. Also, an excessively high trip point can adversely reduce the voltage headroom of other circuits.

Further, there is a need to develop a PUC signal generation arrangement that is independent of other circuits. That is, it is desirable that a PUC signal generation arrangement not have to depend on signals generated by other circuits, at least because those other circuits may not be functioning reliably, especially when the supply voltage is near the trip point.

Conventional solutions involve comparing a resistor-divided supply voltage to a bandgap voltage. (A bandgap circuit provides a voltage reference that is generally considered independent of temperature. For silicon based processes, the bandgap voltage is approximately 1.25 volts, which is defined by the physical properties of silicon.) However, such approaches suffer from false PUC glitches, which may prematurely enable the circuit in question. Moreover, such approaches require sufficient supply headroom for the bandgap circuit before the PUC can enable the logic; this requirement is wasteful because bandgap operation is otherwise not required to operate the logic or any other circuitry on the IC.

An example of such a case would be a low voltage device using “low VT” or “natural VT” MOS devices to create the logic function. Such logic can operate at supply voltages around 1 volt. To require a 1.25 volt bandgap circuit to have headroom before the logic can operate, may require the circuit to have up to a 2 volt supply in order to operate the bandgap. If the chip is powered by a single standard AAA or AA battery, which provides 1.5 volts when new, additional circuitry beyond the bandgap would be required to create a higher supply voltage which allows the bandgap to operate. This expands the problem of additional and wasteful circuitry.

Accordingly, there is a need in the art for PUC signal generation arrangements that preserve supply headroom, generate PUC signals without reliance on other circuits, do not generate false glitches or require special bandgap headroom, and/or automatically compensate for device process variations, temperature, power supply voltage minimum and maximum values, supply voltage dips in case of load transient, and so forth.

### SUMMARY

A power up clear (PUC) signal is generated, based on a value of a supply voltage VCC. A first circuit element (such as an n-channel MOSFET) of a first conductivity type having a first characteristic threshold voltage, and a second circuit element (such as p-channel MOSFET) of a second conductivity type having a second characteristic threshold voltage, are provided in a PUC signal generating circuit. A first circuit portion (including the first circuit element) is configured to provide a first comparison input signal, and a second circuit portion (including the second circuit element) is configured to provide a second comparison input signal. A comparator COMP compares the first and second comparison input signals to cause the PUC signal to transition to an active state when one of the first and second comparison signals crosses another of the first and second comparison signals, in response to an increasing magnitude of the supply voltage during power up.

### BRIEF DESCRIPTION OF THE DRAWINGS

A more complete appreciation of the described embodiments is better understood by reference to the following Detailed Description considered in connection with the accompanying drawings, in which like reference numerals refer to identical or corresponding parts throughout, and in which:

FIG. 1 is a circuit diagram illustrating a power up clear (PUC) signal generator according to one embodiment; and

FIG. 2 illustrates an embodiment of comparator COMP from FIG. 1.

### DETAILED DESCRIPTION

In describing embodiments illustrated in the drawings, specific terminology is employed for the sake of clarity. However, the invention is not intended to be limited to the specific terminology so selected, and it is to be understood that each specific element includes all technical equivalents that operate in a similar manner to accomplish a similar purpose. Various terms that are used in this specification are to be given their broadest reasonable interpretation when used to interpret the claims.

Moreover, features and procedures whose implementations are well known to those skilled in the art are omitted for brevity. For example, design, selection, and implementation of basic electronic circuit elements such as comparators, signal level shifters, buffers, inverters and other logic elements, current and voltage sources, diodes (including “MOSFET diodes”), bipolar transistors, metal oxide semiconductor field effect transistors (MOSFETs), transmission gates, delay elements, and the like, lie within the ability of those skilled in the art, and accordingly any detailed discussion thereof may be omitted.

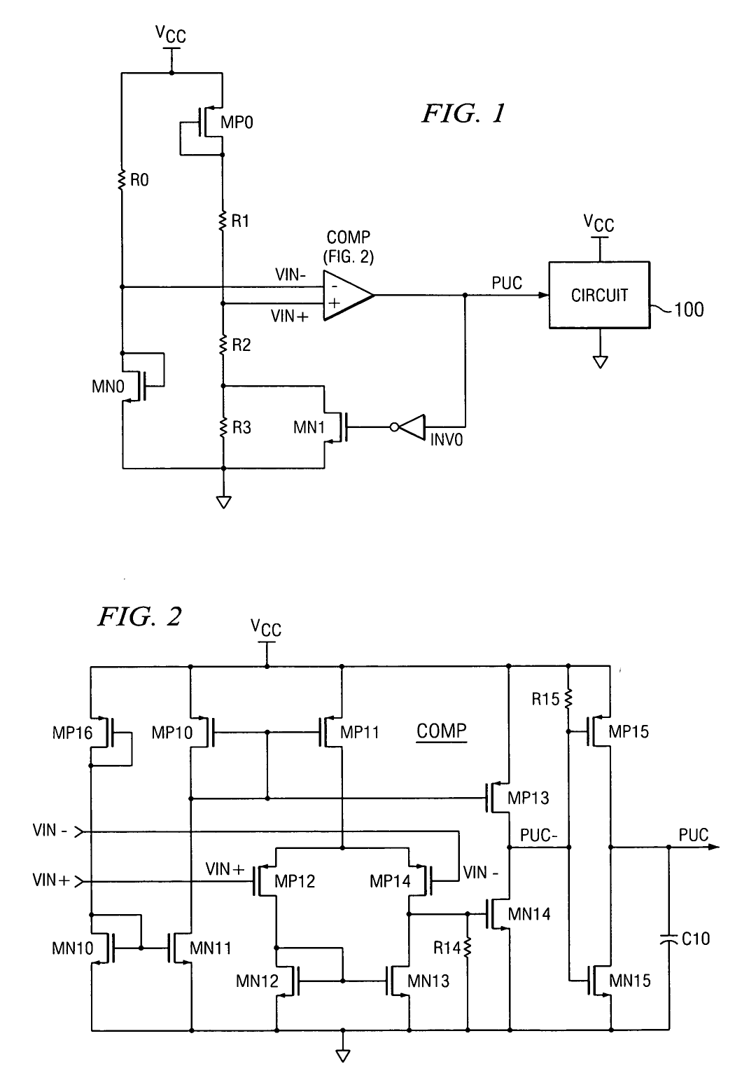

FIG. 1 is a circuit diagram illustrating a power up clear (PUC) signal generator according to one embodiment. Upon power up, the PUC signal enables or initiates operation of a circuit 100. Circuit 100 operates with the same supply voltage VCC as the PUC circuit, or on a signal derived from VCC or directly related to it.

In one embodiment, the PUC signal generator includes devices (such as n-channel and p-channel MOSFETs) that have the same or equivalent characteristic threshold voltages as devices within circuit 100. In this arrangement, any device process variations and any temperature changes that affect the performance characteristics of elements in circuit 100 are likewise reflected in the performance characteristics of the devices in the PUC signal generation arrangement. Thus, the PUC's devices dynamically mimic the circuit's devices, providing a PUC signal that is consistently appropriate to the corresponding circuit 100, despite any device process variations or temperature changes.

Referring more specifically to the details of FIG. 1, between supply voltage VCC and ground, a resistor R0 and an “MOS diode” MN0 are connected in series. As understood herein, an MOS diode is a MOSFET with its gate and drain shorted such that it functions like a diode.

As voltage across MN0 rises to exceed the threshold voltage V_{TN} of MN0 (for example, 1 volt, but varying with device technology and fabrication process), the gate-drain connection effectively limits the voltage at that gate-drain node to that threshold voltage above ground level. Collectively, R0 and MN0 provide a small current (example: 25 μA) that is determined by the voltage between the MN0 threshold and VCC, and the value of R0.

The node between R0 and MN0 provides a first voltage VIN− to the negative input of a comparator COMP. In operation, during power up, VCC increases, as does the voltage VIN− across MN0 until the characteristic MN0 threshold voltage V_{TN} is reached. After the threshold is reached, VIN− remains at V_{TN} (assuming a monotonic rise in VCC).

Between VCC and ground are a series-connected MOS diode MP0 and a voltage ladder including series-connected resistors R1, R2 and R3. The node between R1 and R2 defines a signal VIN+ that is connected to the positive input of comparator COMP.

MP0 functions as MOSFET diode in a manner analogous to MN0. When the voltage across MP0 grows to exceed the p-channel MOSFET threshold voltage V_{TP} (example: 1 volt, but varying with device technology and fabrication process), MN0 holds the voltage across itself at that level (again, assuming a monotonic rise in VCC). The values of R1 and R2+R3 are chosen so that the VIN+ input to the comparator is a multiple of (VCC−V_{TP}), where V_{TP} is the threshold voltage of p-channel MOSFETs such as MP0.

In one embodiment, resistors can be chosen so that VIN+ is 1.7*V_{TN} at the point which the PUC output is toggled to a logic high. (V_{TN} is the threshold voltage of n-channel MOSFETs.) Although VIN+ is a multiple of (VCC−V_{TP}), its value is calculated as a function of V_{TN} to determine the voltage threshold of the PUC circuit. This calculation can be seen from Equations 1-5, discussed in detail below.

During power up operation, VCC rises from ground toward an ultimate value, such as, for example, 3 volts. Initially, VCC is zero, so that both MN0 and MP0 are off and both inputs to COMP are zero; accordingly, the PUC signal provided by the comparator COMP is low.

As VCC rises, it soon exceeds V_{TN} so that MN0 turns on and VIN− is clamped at V_{TN} (example: 1 volt). At the time MN0 begins to conduct, MP0 also barely begins to conduct, so that little current flows through MP0 and R1, R2, R3. Accordingly, VIN+ is small, less than VIN−, and comparator COMP's output signal PUC remains low.

However, as, VCC increases, VIN− remains essentially constant and equal to V_{TN}, but VIN+ increases in proportion to voltage (VCC−V_{TP}). Eventually, VCC reaches a value that causes VIN+ to exceed the constant voltage reference VIN− present at the negative input to COMP. At this time, the comparator's output value PUC switches from low to high, thus initiating or enabling circuit 100 to perform its operations. It is also envisioned that the leading edge of the PUC signal can be input to an edge detector or monostable multi-vibrator, so as to provide a limited-duration pulse that “resets” circuit 100, as distinguished from “enabling” it for the duration that VCC is high.

Also illustrated in FIG. 1 is an inverter INV0 that receives the PUC output from comparator COMP and drives the gate of an n-channel MOSFET MN1. Based on the binary value of the inverted PUC signal, MN1 adjusts the value of VIN+ to perform a hysteresis function. Early in the power up process, after VCC>V_{TN} but when PUC is still low, the gate of MN1 is high, thus causing MN1 to conduct and provide a short circuit from R2 to ground, effectively removing R3 from the circuit.

However, when PUC switches from low to high, the gate of MN1 transitions from high to low, turning MN1 “off” (into a high-resistance state) and effectively returning R3 to the circuit. After the PUC signal goes high, the addition of R3 to the circuit effectively raises the value of voltage VIN+ (assuming a constant VCC). Therefore, if VCC does change thereafter, it will have to drop a given voltage margin below the value that originally triggered PUC to go high in the first place. This hysteresis function helps to assure that as VCC climbs, small downward glitches in VCC do not cause comparator COMP to output a PUC that bounces between high and low logic levels. In this manner, the PUC signal is more stable despite glitches or AC noise in VCC.

FIG. 2 illustrates an embodiment of comparator COMP from FIG. 1. Much of FIG. 2 operates as a conventional comparator; however, certain additional features are provided as discussed below.

Referring to FIG. 2, a p-channel MOSFET MP16 and an n-channel MOSFET MN10 are connected in series between VCC and ground. As the gates and drains of MP16, and of MN10, are connected together, MP16 and MN10 operate as diodes. MP16 is configured to be a long-channel device by setting its channel length much greater than its channel width. Accordingly, MP16 essentially acts as a diode with a large series resistance. Accordingly, only a small bias leakage current (for example, on the order of 10 μA) flows through the diode pair formed from MP16 and MN10.

An n-channel MOSFET MN1, whose gate is connected to the gate and drain of MN10, mirrors the current through MN10. A p-channel MOSFET MP10 is connected in series between VCC and ground with MN11. MP10's gate and drain are connected so that it, also, operates as a MOSFET diode. The gate/drain of MP10 are connected to the gates of p-channel MOSFETs MP11 and MP13, whose sources are connected to VCC. MP10, MP11, and MP13 operate together with several p-channel MOSFETs to function as a conventional current mirror.

More specifically, the gates of MP12 and MP14 receive differential comparator input signals VIN+ and VIN−, respectively. A central node joining the drains of MP12 and MP14 is connected to the drain of MP11. MP11 thus provides a current bias that passes in varying proportions through MP12 and MP14, depending on the relative values of VIN+ and VIN−.

The drain of MP12 is connected to ground through a MOSFET diode MN12. The drain of MP14 is connected to ground through MOSFET MN13. The gates of MN12 and MN13 are connected. The drains of MP14 and MN13 drive the gate of an n-channel MOSFET MN14, also being connected to ground through a high resistance R14. MP13 and MN14 are connected in series between VCC and ground, collectively acting as a comparator output stage presenting an “interim” comparator output PUC− that may be considered to be an inverted version of the PUC signal. The PUC− signal is provided on a node joining the drains of MP13 and MN14.

MOSFETs MP15 and MN15 constitute an inverter, being connected in series between VCC and ground and receiving the PUC− interim comparator output at their respective gates. The final PUC output signal is output at the node joining the drains of MP15 and MN15, the PUC signal being formed into smooth ramp signal by a capacitor C10. A high resistance R15 is connected between VCC and the input to inverter MP15/MN15.

Comparator COMP may be designed to operate as a standard Class-A output comparator, commonly known to those skilled in the art. Unfortunately, at low supply voltages, such a comparator may not operate properly. In order to operate properly, the comparator should not output a falsely high logic level on the PUC signal. Accordingly, an additional aspect of the FIG. 2 comparator lies in the addition of R14 and R15.

R14 holds off the gate of MN14, while R15 holds off the gate of MP15 and also turns on MOSFET MN15. This action guarantees that PUC will be at a logic low level until the supply voltage is sufficient for the comparator to operate properly, at which point the PUC signal will be caused by the comparator to toggle to a logic high state at the desired threshold. The addition of resistors R14 and R15 adds an error term commonly known to those skilled in the art as systemic offset. By choosing the values of R14 and R15 to be sufficiently large, the systemic offset becomes negligible while maintaining the desired feature to prevent falsely generated logic high PUC output signals.

Accordingly, when VIN+ finally exceeds VIN−, this operation causes the interim comparator output PUC− at the input of inverter MP15/MN15 to transition from high to low. This interim comparator output PUC− is inverted to produce the PUC signal that transitions from low to high and drives circuit 100 (FIG. 1).

It is understood that the substrates of p-MOSFETs are connected to VCC, and the substrates of n-MOSFETs are connected to ground. These connections are not specifically shown in FIGS. 1, 2 to avoid clutter.

Circuit elements in FIGS. 1 and 2 may be designed in accordance with the following example values.
R0: 100 KΩ
R1: 56 KΩ
R2: 80 KΩ
R3: 20 KΩ
R14: 1 MΩ
R15: 1 MΩ
C10: May be implemented as an n-channel or p-channel “MOS capacitor” (gate connected to PUC output line; source and drain connected to ground), or as any other available capacitor type in the process technology used.

Of course, actual values used in different applications and in different technologies may be different from those listed. Accordingly, it is clear that the listed component values are not to limit the scope of the claims.

The following derivation further illustrates to those skilled in the art, how PUC signal generation arrangements may be designed in one scenario. Preliminarily, the inventors have noted that MOS digital circuits (inverters, AND gates, flip-flops, and so forth) operate properly when their power supply voltage is greater than a sum of an NMOS transistor threshold voltage and PMOS transistor threshold voltage, that is: V_{TN}+V_{TP}. Accordingly, the FIG. 1 embodiment's PUC signal is based on the sum of MOS transistor threshold voltages.

If supply voltage VCC is greater than V_{TN} then:
VIN−=V_{TN} (Equation 1)

Similarly, when VCC becomes greater than V_{TN} then, assuming R3 is removed from the circuit by the action of hysteresis elements INV0 and MN1:

$$VIN += ( VCC - {V}_{TP} ) \frac{R2}{( R1 + R2 )} \qquad ( Equation 2 )$$

The comparator's PUC output signal transitions from low to high, only when VIN+>VIN−. Therefore:

$$( VCC - {V}_{TP} ) \frac{R2}{( R1 + R2 )} > {V}_{TN} \qquad ( Equation 3 )$$

Solving equation (3) for VCC yields:

$$VCC > {V}_{TP} + {V}_{TN} \frac{R1 + R2}{R2} \qquad ( Equation 4 )$$

Equation (4) shows that the disclosed arrangement trips at a voltage, ΔV above (V_{TP}+V_{TN}). Significantly, this trip point is defined by R1 and R2, an expression that is independent of process and temperature variations.

Resistors R0, R1, R2 and R3 perform several functions:
R1 & R2 adjust the PUC trip point with respect to VCC voltage;
R0, R1, R2 and R3 limit current flow through branches containing MOS transistors; and
R3 provides a hysteresis around the trip point.

As shown in FIG. 2, comparator COMP compares VIN− and VIN+ to provide the PUC signal. The power supply of the comparator should be greater than (V_{TN}+V_{TP}+2V_{DS}), where V_{DS} is the drain-to-source voltage required for an NMOS or PMOS to conduct current. Proper choice of resistor values R1 and R2 guarantees that the PUC signal is generated for supply voltage VCC when:
VCC>V_{TP}+V_{TN}+2V_{DS} (Equation 5)

If VCC is less than the value defined in Equation (5), the comparator's PUC output signal is kept low by resistors R14, R15 (FIG. 2). Once VCC is greater than the value defined in Equation (5), the comparator is known to be properly functioning and will keep the PUC output low until such time that VCC is also greater than the value defined in Equation (4).

The disclosed PUC signal generation arrangement detects minimum power supply voltage required by digital circuits for normal operation. The PUC signal tracks MOS transistor threshold voltages, regardless of process variations and temperature changes. By implication, headroom problems are not created for other circuits in a system. The disclosed arrangement does not require an externally supplied reference voltage, such as a bandgap, to have headroom first in order to operate. Moreover, the disclosed arrangement does not require additional bias voltages or currents in order to operate, and in fact does not require input from any other circuits in order to operate.

From the foregoing, it will be apparent to those skilled in the art that a variety of methods, systems, and other arrangements, are provided.

The present disclosure provides support for an arrangement for generating a power up clear (PUC) signal based on a value of a supply voltage. The arrangement includes a first circuit element (MN0) of a first conductivity type having a first characteristic threshold voltage; a second circuit element (MP0) of a second conductivity type having a second characteristic threshold voltage; a first circuit (MN0, R0), including the first circuit element, configured to provide a first comparison input signal (VIN−); a second circuit (MP0, R1, R2), including the second circuit element, configured to provide a second comparison input signal (VIN+); and a comparator (COMP) for comparing the first and second comparison input signals, to cause the PUC signal to transition to an active state when one of the first and second comparison signals crosses another of the first and second comparison signals in response to an increasing magnitude of the supply voltage.

The comparator may determine the PUC signal based only on the first and second comparison input signals, without reference to any externally supplied reference voltages or currents or bias voltages or currents.

The first characteristic threshold voltage may be an n-channel MOSFET threshold voltage (V_{TN}). The first circuit may include an n-channel MOSFET (MN0); and a resistance (R0), operative with the n-channel MOSFET so as to provide the first comparison signal (VIN−) to the comparator. The first circuit may be configured to provide the first comparison signal (VIN−) that is substantially constant after the supply voltage exceeds V_{TN}.

The second characteristic threshold voltage may be a p-channel MOSFET threshold voltage (V_{TP}). The second circuit may include a p-channel MOSFET (MP0); and a resistance ladder (R1, R2), operative with the p-channel MOSFET so as to provide the second comparison signal (VIN+) to the comparator. The second circuit may be configured to provide the second comparison signal to (VIN+) that varies as a function of the supply voltage and crosses the first comparison signal when the supply voltage has increased to a value exceeding a sum of the first and second characteristic threshold voltages.

The arrangement may further have a hysteresis arrangement, configured to ensure that, after the comparator causes the PUC signal to transition to an active state in response to the supply voltage exceeding a first level, the PUC signal remains in the active state for so long as the supply voltage continues to exceed a second level that is a non-zero voltage margin smaller than the first level. The hysteresis arrangement may include a switch element (MN1), configured to adjust at least one of the first and second comparison signals. The hysteresis arrangement may further include a hysteresis resistance (R3); and the switch element may include a transistor (MN1) that selectively removes the hysteresis resistance in response to a first state of the PUC signal and replaces the hysteresis resistance in response to a second state of the PUC signal. The transistor (MN1) may selectively short out the hysteresis resistance (R3) in response to the non-active state of the PUC signal, and may enter a high impedance state so as to replace the hysteresis resistance in response to the active state of the PUC signal, so as to adjust the second comparison signal (VIN+).

The first characteristic threshold voltage may be an n-channel MOSFET threshold voltage (V_{TN}); the first circuit may include an n-channel MOSFET (MN0) and a resistance (R0), operative with the n-channel MOSFET so as to provide the first comparison signal (VIN−) to the comparator; the first circuit may be configured to provide the first comparison signal (VIN−) that is substantially constant after the supply voltage exceeds V_{TN}; the second characteristic threshold voltage may be a p-channel MOSFET threshold voltage (V_{TP}); the second circuit may include a p-channel MOSFET (MP0), and a resistance ladder (R1, R2) that is operative with the p-channel MOSFET so as to provide the second comparison signal (VIN+) to the comparator; and the second circuit may be configured to provide the second comparison signal (VIN+) that varies as a function of the supply voltage and crosses the first comparison signal when the supply voltage has increased to a value exceeding a sum of the first and second characteristic threshold voltages.

The present disclosure also provides support for a system comprising the PUC signal generating arrangement described above, and further having a receiving circuit that is configured and arranged to receive the PUC signal, that is connected to the same supply voltage as the PUC signal generating circuit, and that includes elements of a same type as the first circuit element (MN0) of the first conductivity type and the second circuit element (MP0) of the second conductivity type.

The present disclosure provides support for a method for generating a power up clear (PUC) signal based on a value of a supply voltage. The method may involve providing a first comparison input signal (VIN−) that is based on a first characteristic threshold voltage of a first circuit element of a first conductivity type; providing a second comparison input signal (VIN+) that is based on a second characteristic threshold voltage of a second circuit element of a second conductivity type; and comparing the first and second comparison input signals, to cause the PUC signal to transition to an active state when one of the first and second comparison signals crosses another of the first and second comparison signals in response to an increasing magnitude of the supply voltage.

The comparing step may constitute determining the PUC signal based only on the first and second characteristic threshold voltages, without reference to any externally supplied reference voltages or currents or bias voltages or currents.

The first characteristic threshold voltage may be an n-channel MOSFET threshold voltage (V_{TN}), and the second characteristic threshold voltage may be a p-channel MOSFET threshold voltage (V_{TP}).

The comparing step may constitute determining the PUC signal based only on (1) an n-channel MOSFET threshold voltage constituting the first characteristic threshold voltage, and (2) a p-channel MOSFET threshold voltage constituting the second characteristic threshold voltage, without reference to any externally supplied reference voltages or currents or bias voltages or currents.

The present disclosure further provides support for systems configured to perform the methods described above.

Many alternatives, modifications, and variations will be apparent to those skilled in the art in light of the above teachings. For example, use of devices and device thresholds other than those discussed above, lies within the scope of the present invention. Further, varying the design, arrangement, and operation of components in the PUC signal generation circuit, lies within the contemplation of the invention. It is therefore to be understood that within the scope of the appended claims and their equivalents, the invention may be practiced otherwise than as specifically described herein.

1. An arrangement for generating a power up clear (PUC) signal based on a value of a supply voltage, the arrangement comprising:
a first circuit element of a first conductivity type having a first characteristic threshold voltage;
a second circuit element of a second conductivity type having a second characteristic threshold voltage;
a first circuit, including the first circuit element, configured to provide a first comparison input signal;
a second circuit, including the second circuit element, configured to provide a second comparison input signal; and
a comparator for comparing the first and second comparison input signals, to cause the PUC signal to transition to an active state when one of the first and second comparison signals crosses another of the first and second comparison signals in response to an increasing magnitude of the supply voltage.

2. The arrangement of claim 1, wherein:
the comparator determines the PUC signal based only on the first and second comparison input signals, without reference to any externally supplied reference voltages or currents or bias voltages or currents.

3. The arrangement of claim 1, wherein:
the first characteristic threshold voltage is an n-channel MOSFET threshold voltage.

4. The arrangement of claim 3, wherein the first circuit includes:
an n-channel MOSFET; and
a resistance, operative with the n-channel MOSFET so as to provide the first comparison signal to the comparator.

5. The arrangement of claim 4, wherein:
the first circuit is configured to provide the first comparison signal that is substantially constant after the supply voltage exceeds the n-channel MOSFET threshold voltage.

6. The arrangement of claim 1, wherein:
the second characteristic threshold voltage is a p-channel MOSFET threshold voltage.

7. The arrangement of claim 6, wherein the second circuit includes:
a p-channel MOSFET; and
a resistance ladder, operative with the p-channel MOSFET so as to provide the second comparison signal to the comparator.

8. The arrangement of claim 7, wherein:
the second circuit is configured to provide the second comparison signal to that varies as a function of the supply voltage and crosses the first comparison signal when the supply voltage has increased to a value exceeding a sum of the first and second characteristic threshold voltages.

9. An arrangement of claim 1, further comprising:
a hysteresis arrangement, configured to ensure that, after the comparator causes the PUC signal to transition to an active state in response to the supply voltage exceeding a first level, the PUC signal remains in the active state for so long as the supply voltage continues to exceed a second level that is a non-zero voltage margin smaller than the first level.

10. The arrangement of claim 9, wherein the hysteresis arrangement includes:
a switch element, configured to adjust at least one of the first and second comparison signals.

11. The arrangement of claim 10, wherein:
the hysteresis arrangement further includes a hysteresis resistance; and
the switch element includes a transistor that selectively removes the hysteresis resistance in response to a first state of the PUC signal and replaces the hysteresis resistance in response to a second state of the PUC signal.

12. The arrangement of claim 11, wherein:
the transistor selectively shorts out the hysteresis resistance in response to the non-active state of the PUC signal, and enters a high impedance state so as to replace the hysteresis resistance in response to the active state of the PUC signal, so as to adjust the second comparison signal.

13. The arrangement of claim 1, wherein:
the first characteristic threshold voltage is an n-channel MOSFET threshold voltage;
the first circuit includes an n-channel MOSFET and a resistance, operative with the n-channel MOSFET so as to provide the first comparison signal to the comparator;
the first circuit is configured to provide the first comparison signal that is substantially constant after the supply voltage exceeds the n-channel MOSFET threshold voltage;
the second characteristic threshold voltage is a p-channel MOSFET threshold voltage;
the second circuit includes a p-channel MOSFET, and a resistance ladder that is operative with the p-channel MOSFET so as to provide the second comparison signal to the comparator; and
the second circuit is configured to provide the second comparison signal that varies as a function of the supply voltage and crosses the first comparison signal when the supply voltage has increased to a value exceeding a sum of the first and second characteristic threshold voltages.

14. A system comprising the PUC signal generating arrangement of claim 1, and further comprising:
a receiving circuit that is configured and arranged to receive the PUC signal, that is connected to the same supply voltage as the PUC signal generating circuit, and that includes elements of a same type as the first circuit element of the first conductivity type and the second circuit element of the second conductivity type.

15. A method for generating a power up clear (PUC) signal based on a value of a supply voltage, the method comprising:
providing a first comparison input signal that is based on a first characteristic threshold voltage of a first circuit element of a first conductivity type;
providing a second comparison input signal that is based on a second characteristic threshold voltage of a second circuit element of a second conductivity type; and
comparing the first and second comparison input signals, to cause the PUC signal to transition to an active state when one of the first and second comparison signals crosses another of the first and second comparison signals in response to an increasing magnitude of the supply voltage.

16. The method of claim 15, wherein the comparing step constitutes:
determining the PUC signal based only on the first and second characteristic threshold voltages, without reference to any externally supplied reference voltages or currents or bias voltages or currents.

17. The method of claim 15, wherein:
the first characteristic threshold voltage is an n-channel MOSFET threshold voltage.

18. The method of claim 15, wherein:
the second characteristic threshold voltage is a p-channel MOSFET threshold voltage.

19. The method of claim 15, wherein the comparing step constitutes:
determining the PUC signal based only on (1) an n-channel MOSFET threshold voltage constituting the first characteristic threshold voltage, and (2) a p-channel MOSFET threshold voltage constituting the second characteristic threshold voltage, without reference to any externally supplied reference voltages or currents or bias voltages or currents.

20. A system configured to perform the method of claim 15.
